(19) United States
(12) Patent Application Publication
(10) Pub. No.: US 2024/0276826 A1
(43) Pub. Date: Aug. 15, 2024

(54) DISPLAY DEVICE

(71) Applicant: Samsung Display Co., Ltd., Yongin-Si, Gyeonggi-Do (KR)

(72) Inventors: SANGJI PARK, Yongin-si, Gyeonggi-do (KR); CHEOL SHIN, Yongin-si, Gyeonggi-do (KR); KEUNCHAN OH, Yongin-si, Gyeonggi-do (KR); DOKYUNG YOUN, Yongin-si, Gyeonggi-do (KR); SONGEE LEE, Yongin-si, Gyeonggi-do (KR); SUN-KYU JOO, Yongin-si, Gyeonggi-do (KR); WOO-MAN JI, Yongin-si, Gyeonggi-do (KR); WONSUK HAN, Yongin-si, Gyeonggi-do (KR); TAE HYUNG HWANG, Yongin-si, Gyeonggi-do (KR)

(21) Appl. No.: 18/537,813

(22) Filed: Dec. 13, 2023

(30) Foreign Application Priority Data
Feb. 13, 2023 (KR) 10-2023-0018788

(51) Int. Cl. H10K 59/38; H10K 59/122; H10K 59/80

(52) U.S. Cl. CPC H10K 59/38; H10K 59/122; H10K 59/877

(57) ABSTRACT

A display device includes: a pixel electrode layer disposed on a substrate, a light emitting layer disposed on the pixel electrode layer, a bank layer disposed on the light emitting layer and defining first, second, and third openings, a first color conversion layer disposed in the first opening and including first quantum dots, and a scattering layer disposed in a layer between the pixel electrode and the bank layer, such that the scattering layer and at least a part of the first color conversion layer cover mutually exclusive parts of the substrate, the scattering layer including a base resin and a plurality of scattering particles dispersed in the base resin.

### CROSS-REFERENCE TO RELATED APPLICATION

This application claims priority to and benefits, under 35 U.S.C. § 119, of Korean Patent Application No. 10-2023-0018788 filed on Feb. 13, 2023 in the Korean Intellectual Property Office (KIPO), the entire contents of which are hereby incorporated by reference.

### BACKGROUND

### 1. Technical Field

This disclosure relates generally to a display device. More particularly, this disclosure relates to a display device that provides visual information.

### 2. Description of the Related Art

With the development of information technology, display devices, which connect a user to information, have become increasingly important. For example, the use of a display device such as a liquid crystal display device, an organic light emitting display device, a plasma display device, and the like is increasing.

Recently, an organic light emitting display device including an organic light emitting element and a color conversion layer has been receiving attention. The color conversion layer may convert a wavelength of light emitted from the organic light emitting element. Accordingly, the organic light emitting display device may emit light having a color different from a color of incident light.

### SUMMARY

This disclosure pertains to a display device with improved viewing angle characteristic.

A display device according to embodiments of the present disclosure includes a pixel electrode layer disposed on a substrate, a light emitting layer disposed on the pixel electrode layer, a bank layer disposed on the light emitting layer and defining first, second, and third openings, a first color conversion layer disposed in the first opening and including first quantum dots, and a scattering layer disposed in a layer between the pixel electrode layer and the bank layer such that the scattering layer and at least a part of the first color conversion layer cover mutually exclusive parts of the substrate, the scattering layer including a base resin and a plurality of scattering particles dispersed in the base resin.

The scattering layer may form a base of the third opening.

In an embodiment, the display device may further include a second color conversion layer disposed in the second opening and including quantum dots. The scattering layer and at least a part of the second color conversion layer may cover mutually exclusive parts of the substrate.

The scattering layer may further overlap the bank layer.

The scattering layer may overlap less than all of the bank layer.

The display device may further include an encapsulation layer disposed on the light emitting layer. The scattering layer may be disposed in a layer between the encapsulation layer and the bank layer.

The display device may further include an encapsulation layer disposed on the light emitting layer. The scattering layer may be disposed between the light emitting layer and the encapsulation layer.

The display device may further include a pixel defining layer defining a pixel opening that extends to at least a part of the pixel electrode layer and an encapsulation layer disposed on the light emitting layer and the pixel defining layer. A part of the scattering layer may be disposed between the pixel defining layer and the encapsulation layer and another part of the scattering layer may be disposed between the pixel electrode layer and the light emitting layer.

The display device may include a resin in the third opening, the resin being homogeneous and having high light transmittance.

The scattering layer may have a thickness of about 10 nm to about 10000 nm.

Each of the scattering particles may include at least one of TiO₂, Sb₂O₃, CaO, and In₂O₃.

A display device according to embodiments of the present disclosure includes a substrate including first, second, and third emitting areas that emit light of different colors and a light blocking area between the first, second, and third emitting areas, a pixel electrode layer disposed on the substrate, first, second, and third light emitting layers disposed on the pixel electrode layer and in the first, second, and third emitting areas, respectively, a bank layer disposed on the first, second, and third light emitting layers and defining first, second, and third openings above the first, second, and third emitting areas, respectively, a first color conversion layer disposed in the first opening and including first quantum dots, and a scattering layer disposed in a layer between the pixel electrode layer and the bank layer such that the scattering layer and at least a part of the first color conversion layer cover mutually exclusive parts of the substrate, the scattering layer including a base resin and a plurality of scattering particles dispersed in the base resin.

The scattering layer may overlap the third light emitting area.

The display device may further include a second color conversion layer disposed in the second opening and including quantum dots.

The scattering layer may overlap the bank layer.

The scattering layer may partially overlap the bank layer.

The display device may further include an encapsulation layer disposed on the light emitting layer. The scattering layer may be disposed in a layer between the encapsulation layer and the bank layer.

The display device may further include an encapsulation layer disposed on the light emitting layer. The scattering layer may be disposed between the light emitting layer and the encapsulation layer.

With the display device may include a resin in the third opening, the resin being homogeneous and having high light transmittance.

In an embodiment, the first light emitting area may emit red light, the second light emitting area may emit green light, and the third light emitting area may emit blue light.

A display device according to an embodiment of the present disclosure may include a scattering layer disposed on a pixel electrode layer and including a base resin and a plurality of scattering particles dispersed in the base resin, a bank layer disposed on the scattering layer and defining first, second, and third openings, a first color conversion layer disposed in the first opening and including first quantum dots, and a second color conversion layer disposed in the second opening and including second quantum dots. The scattering layer may overlap the third opening and not completely overlap the first and second color conversion layers in a plan view. Accordingly, viewing angle characteristic of the display device can be improved.

In addition, in the display device according to an embodiment of the present disclosure, a resin having high light transmittance without scattering particles may be filled in the third opening. Accordingly, light efficiency of the display device can be improved, and a high-resolution display device can be implemented.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating a display device according to an embodiment of the present disclosure.

FIG. 2 is a cross-sectional view taken along line I-I′ of FIG. 1.

FIG. 3 is a plan view illustrating the display device of FIGS. 1 and 2.

FIG. 4 is a cross-sectional view taken along line II-II′ of FIG. 3.

FIG. 5 is an enlarged cross-sectional view of area A of FIG. 4.

FIG. 6 is a cross-sectional view for explaining a first color conversion layer and a second color conversion layer of FIG. 4.

FIGS. 7, 8, 9, 10, 11, 12, 13, and 14 are cross-sectional views illustrating a method of manufacturing the display device of FIG. 4.

FIG. 15 is a cross-sectional view illustrating a display device according to another embodiment of the present disclosure.

FIG. 16 is a cross-sectional view illustrating a display device according to still another embodiment of the present disclosure.

FIG. 17 is a cross-sectional view illustrating a display device according to still another embodiment of the present disclosure.

### DETAILED DESCRIPTION OF THE EMBODIMENTS

Hereinafter, a display device according to embodiments of the present disclosure will be explained in detail with reference to the accompanying drawings. The same reference numerals are used for the same components in the drawings, and redundant descriptions of the same components will be omitted.

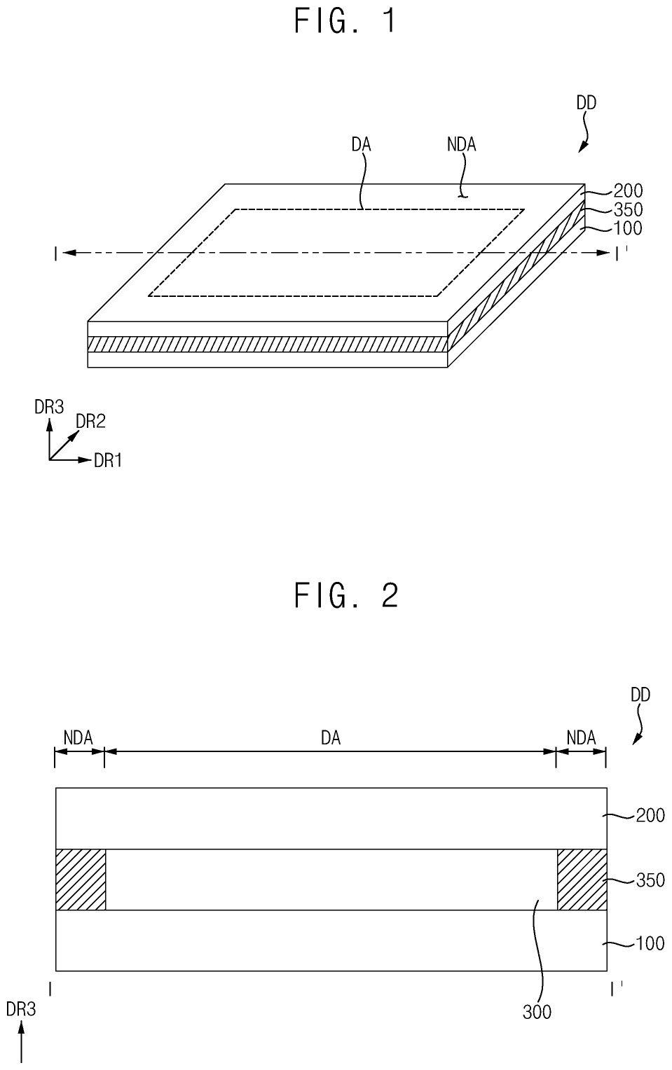

FIG. 1 is a perspective view illustrating a display device according to an embodiment of the present disclosure. FIG. 2 is a cross-sectional view taken along line I-I′ of FIG. 1.

Referring to FIGS. 1 and 2, the display device DD according to an embodiment of the present disclosure may include a lower structure 100, a sealing portion 350, a filling layer 300, and an upper structure 200.

The display device DD may be divided into a display area DA and a non-display area NDA. The display area DA may be defined as an area that displays an image, and the non-display area NDA may be defined as an area not that displays an image. The non-display area NDA may be positioned around the display area DA. For example, the non-display area NDA may surround the display area DA.

The lower structure 100 may include a substrate, insulating layers, a transistor, and a light emitting element. A detailed description of the lower structure 100 will be described later.

The upper structure 200 may be disposed on the lower structure 100. The upper structure 200 may face the lower structure 100. The upper structure 200 may include a color conversion layer that converts a wavelength of light emitted from the light emitting element. A detailed description of the upper structure 200 will be described later.

The sealing portion 350 may be disposed between the lower structure 100 and the upper structure 200 in the non-display area NDA. The sealing portion 350 may be disposed along the edges of the lower structure 100 and the upper structure 200 in the non-display area NDA to surround the display area DA in a plan view. In addition, the lower structure 100 and the upper structure 200 may be coupled through the sealing portion 350. The sealing portion 350 may include an organic material. For example, the sealing portion 350 may include an epoxy resin and the like. However, embodiments of the present disclosure are not limited, and the sealing portion 350 may include various organic materials.

The filling layer 300 may be disposed between the lower structure 100 and the upper structure 200. The filling layer 300 may fill between the lower structure 100 and the upper structure 200. The filling layer 300 may include a resin having a high light transmittance. For example, the filling layer 300 may include an organic material. Examples of materials that can be used for the filling layer 300 may include silicone-based resin, epoxy-based resins, and the like. These may be used alone or in combination with each other. However, embodiments of the present disclosure are not limited, and the filling layer 300 may include various organic materials. In other embodiments, the filling layer 300 may be omitted.

In this specification, a plane may be defined as a first direction DR1 and a second direction DR2 crossing the first direction DR1. For example, the second direction DR2 may be perpendicular to the first direction DR1. In addition, a third direction DR3 may be perpendicular to the plane.

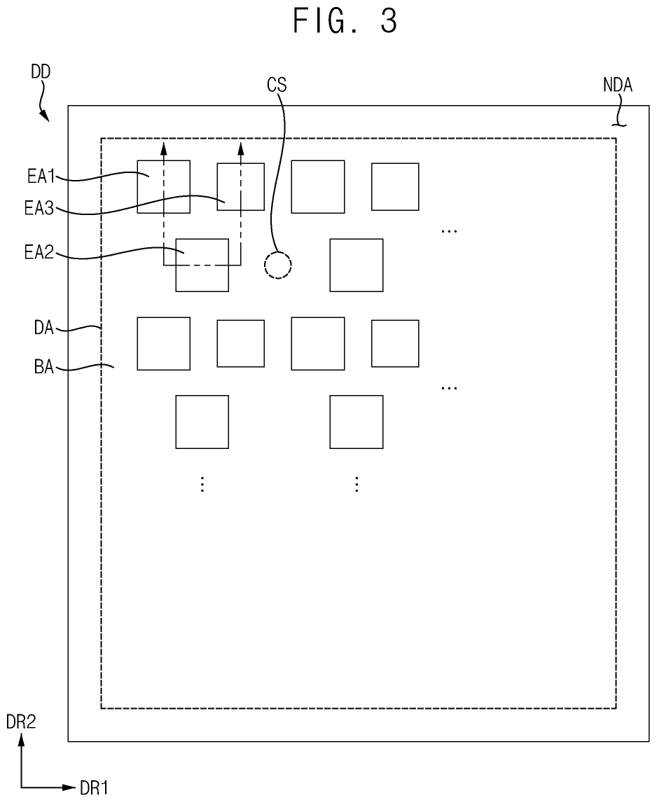

FIG. 3 is a plan view illustrating the display device of FIGS. 1 and 2.

Referring to FIGS. 1, 2 and 3, as described above, the display device DD may include the display area DA and the non-display area NDA. Here, the display area DA may include a first light emitting area EA1, a second light emitting area EA2, a third light emitting area EA3, and a light blocking area BA.

The first light emitting area EA1, the second light emitting area EA2, and the third light emitting area EA3 may be arranged in the same configuration along the first direction DR1 and the second direction DR2 crossing the first direction DR1. This configuration may repeat across the display area DA. For example, the first light emitting area EA1 and the third light emitting area EA3 may be alternately arranged along the first direction DR1 in a first row, and the second light emitting area EA2 may be repeatedly arranged along the first direction DR1 in a second row adjacent to the first row. In this case, the second light emitting area EA2 may partially share the same coordinates as each of the first and third light emitting areas EA1 and EA3 in the first direction DR1.

Each of the first light emitting area EA1, the second light emitting area EA2, and the third light emitting area EA3 may be an area through which light emitted from the light emitting element exits the display device DD. The first light emitting area EA1, the second light emitting area EA2, and the third light emitting area EA3 may emit light of different colors. For example, the first light emitting area EA1 may emit light of a first color, the second light emitting area EA2 may emit light of a second color, and the third light emitting area EA3 may emit light of a third color.

In an embodiment, the first light emitting area EA1 may emit red light, the second light emitting area EA2 may emit green light, and the third light emitting area EA3 may emit blue light. However, embodiments of the present disclosure are not limited thereto, and for example, the first light emitting area EA1, the second light emitting area EA2, and the third light emitting area EA3 may be combined to emit yellow, cyan, and magenta lights.

In addition, the first light emitting area EA1, the second light emitting area EA2, and the third light emitting area EA3 may emit light of four or more colors. For example, the first light emitting area EA1, the second light emitting area EA2, and the third light emitting area EA3 may combined to further emit at least one of yellow, cyan, and magenta lights in addition to red, green, and blue lights. In addition, the first light emitting area EA1, the second light emitting area EA2, and the third light emitting area EA3 may be combined to further emit white light.

Areas of the first light emitting area EA1, the second light emitting area EA2, and the third light emitting area EA3 may be different from each other. In an embodiment, the area of the first light emitting area EA1 that emits red light may be larger than each of the area of the second light emitting area EA2 that emits green light and the area of the third light emitting area EA3 that emits blue light. In this case, the area of the second light emitting area EA2 may be larger than that of the third light emitting area EA3. However, embodiments of the present disclosure are not limited thereto.

The light blocking area BA may be positioned between the first light emitting area EA1, the second light emitting area EA2, and the third light emitting area EA3. For example, in a plan view, the light blocking area BA may surround the first light emitting area EA1, the second light emitting area EA2, and the third light emitting area EA3. The light blocking area BA may not emit light.

A column spacer CS may be disposed between the lower structure 100 and the upper structure 200. The column spacer CS may overlap the light blocking area BA. The column spacer CS may maintain a constant gap between the lower structure 100 and the upper structure 200 in a process of coupling the lower structure 100 and the upper structure 200. In some embodiments, the column spacer CS may be omitted.

The display device DD may have a rectangular planar shape. For example, the display device DD may include two first sides extending in the first direction DR1 and two second sides extending in the second direction DR2. A corner where the first side and the second side meet may be a right angle. Alternatively, a corner where the first side and the second side of the display device DD meet may form a curved surface.

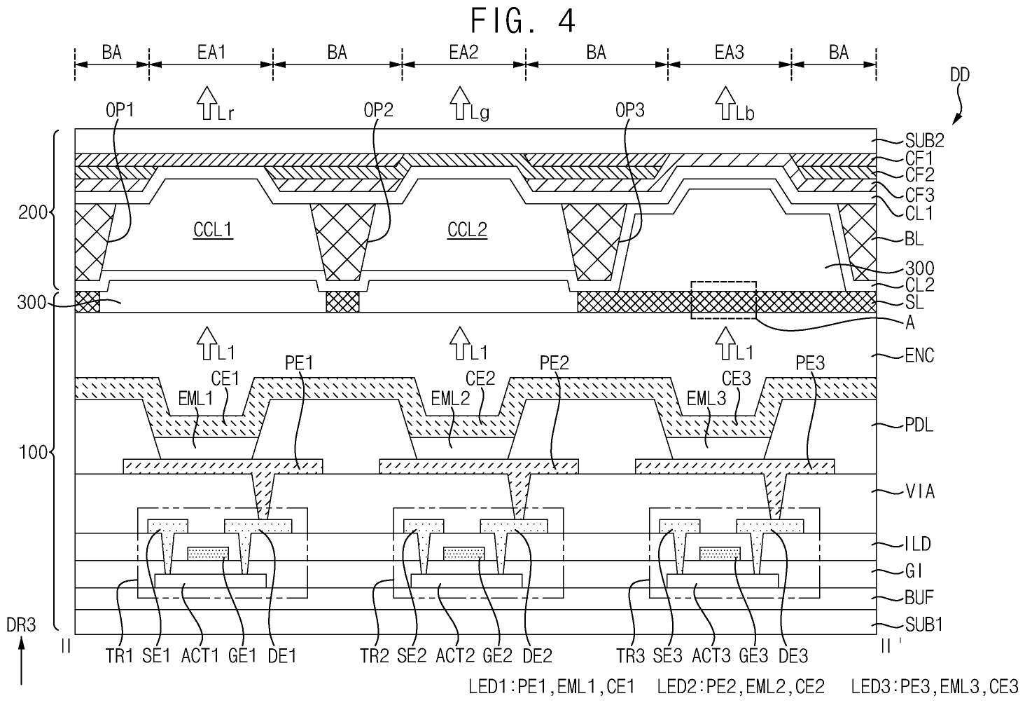

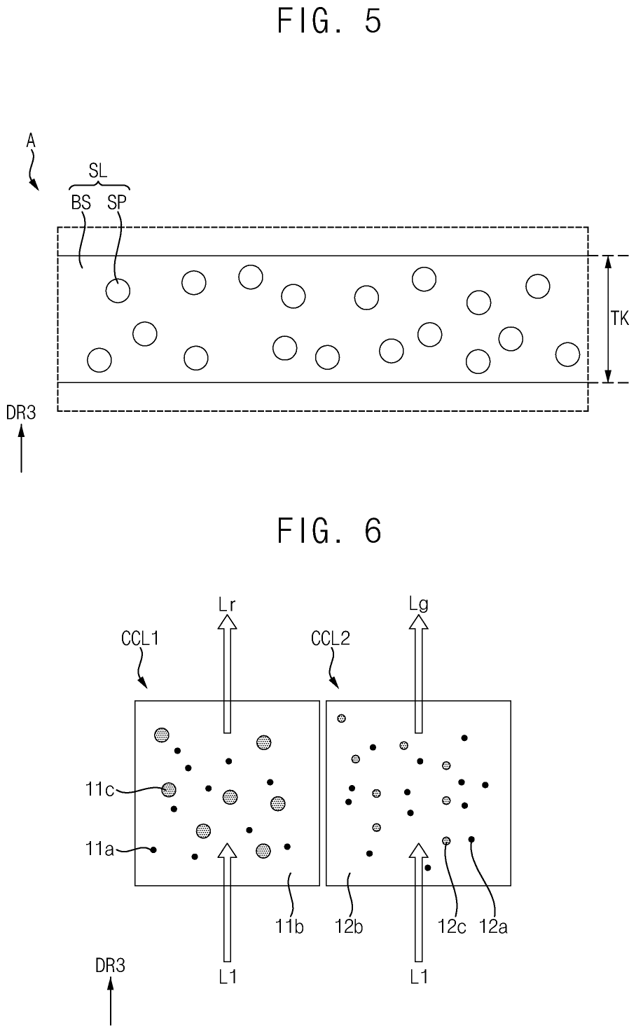

FIG. 4 is a cross-sectional view taken along line II-II′ of FIG. 3. FIG. 5 is an enlarged cross-sectional view of area A of FIG. 4. As shown, each of the first light emitting area EA1, the second light emitting area EA2, and the third light emitting area EA3 have boundaries that substantially align with the outline of the first light emitting layer EML1, the second light emitting layer EML2, and the third light emitting layer EML3, respectively.

Referring to FIG. 4, the display device DD according to an embodiment may include the lower structure 100, the filling layer 300, and the upper structure 200. Here, the lower structure 100 may include a first substrate SUB1, a buffer layer BUF, first, second, and third transistors TR1, TR2, and TR3, a gate insulating layer GI, an interlayer insulating layer ILD, an via insulating layer VIA, a pixel defining layer PDL, first, second, and third light emitting elements LED1, LED2, and LED3, an encapsulation layer ENC, and a scattering layer SL. The upper structure 200 may include a second substrate SUB2, first, second, and third color filters CF1, CF2, and CF3, a first capping layer CL1, a bank layer BL, first and second color conversion layers CCL1 and CCL2, and a second capping layer CL2.

First, the lower structure 100 will be described.

As described above, the display device DD may include the display area DA and the non-display area NDA, and the display area DA may include the first light emitting area EA1, the second light emitting area EA2, the third light emitting area EA3, and the light blocking area BA. As the display area DA of the display device DD includes the first light emitting area EA1, the second light emitting area EA2, the third light emitting area EA3, and the light blocking area BA, the first substrate may include the first light emitting area EA1, the second light emitting area EA2, the third light emitting area EA3, and the light blocking area BA.

The first substrate SUB1 may include a transparent material or an opaque material. The first substrate SUB1 may be formed of a transparent resin substrate. Examples of the transparent resin substrate may include polyimide substrates and the like. In this case, the polyimide substrate may include a first organic layer, a first barrier layer, a second organic layer, and the like. Alternatively, the first substrate SUB1 may include a quartz substrate, a synthetic quartz substrate, a calcium fluoride substrate, an F-doped quartz substrate, soda-lime substrate, non-alkali glass substrate, and the like. These may be used alone or in combination with each other.

The buffer layer BUF may be disposed on the first substrate SUB1. The buffer layer BUF may prevent diffusion of metal atoms or impurities from the first substrate SUB1 to the first, second, and third transistors TR1, TR2, and TR3. In addition, the buffer layer BUF can improve the flatness of the surface of the first substrate SUB1 when the surface of the first substrate SUB1 is not uniform. For example, the buffer layer BUF may include an inorganic material such as silicon oxide, silicon nitride, silicon oxynitride, and the like. These may be used alone or in combination with each other.

The first, second, and third active patterns ACT1, ACT2, and ACT3 may be disposed on the buffer layer BUF. Each of the first, second, and third active patterns ACT1, ACT2, and ACT3 may include a metal oxide semiconductor, an inorganic semiconductor (e.g., amorphous silicon, poly silicon), or an organic semiconductor. Each of the first, second, and third active patterns ACT1, ACT2, and ACT3 may include a source region, a drain region, and a channel region positioned between the source region and the drain region. The first, second, and third active patterns ACT1, ACT2, and ACT3 may be formed through the same process and include the same material.

The metal oxide semiconductor may include a two-component compound (ABₓ), a ternary compound (ABₓC_{y}), a four-component compound (ABₓC_{y}D_{z}), and the like containing indium (In), zinc (Zn), gallium (Ga), tin (Sn), titanium (Ti), aluminum (Al), hafnium (Hf), zirconium (Zr), magnesium (Mg), and the like. For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), and the like. These may be used alone or in combination with each other.

The gate insulating layer GI may be disposed on the buffer layer BUF. The gate insulating layer GI may sufficiently cover the first, second, and third active patterns ACT1, ACT2, and ACT3, and may have a substantially flat upper surface without creating a step around the first, second, and third active patterns ACT1, ACT2, and ACT3. Alternatively, the gate insulating layer GI may cover the first, second, and third active patterns ACT1, ACT2, and ACT3 and may be disposed along the profile of each of the first, second, and third active patterns ACT1, ACT2, and ACT3 to have a uniform thickness. For example, the gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These may be used alone or in combination with each other.

The first, second, and third gate electrodes GE1, GE2, and GE3 may be disposed on the gate insulating layer GI. The first gate electrode GE1 may overlap the channel region of the first active pattern ACT1, the second gate electrode GE2 may overlap the channel region of the second active pattern ACT2, and the third gate electrode GE3 may overlap the channel region of the third active pattern ACT3.

Each of the first, second, and third gate electrodes GE1, GE2, and GE3 may include a metal, an alloy metal nitride, a conductive metal oxide, a transparent conductive material, and the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide may include indium tin oxide, indium zinc oxide, and the like. In addition, examples of the metal nitride may include aluminum nitride (AlNₓ), tungsten nitride (WNₓ), chromium nitride (CrNₓ), and the like. These may be used individually or in combination with each other.

The first, second, and third gate electrodes GE1, GE2, and GE3 may be formed through the same process and include the same material.

The interlayer insulating layer ILD may be disposed on the gate insulating layer GI. The interlayer insulating layer ILD may sufficiently cover the first, second, and third gate electrodes GE1, GE2, and GE3 planarizes the upper surface to avoid creating steps or bumps around the first, second, and third gate electrodes GE1, GE2, and GE3.

Optionally, the interlayer insulating layer ILD may cover the first, second, and third gate electrodes GE1, GE2, and GE3 and may be conformally formed with a uniform thickness on each of first, second, and third gate electrodes GE1, GE2, and GE3. For example, the interlayer insulating layer ILD may include an inorganic material such as silicon oxide, silicon nitride, silicon carbide, silicon oxynitride, silicon oxycarbide, and the like. These may be used alone or in combination with each other.

The first, second, and third source electrodes SE1, SE2, and SE3 may be disposed on the interlayer insulating layer ILD. The first source electrode SE1 may be connected to the source region of the first active pattern ACT1 through a contact hole extending through the gate insulating layer GI and the interlayer insulating layer ILD. The second source electrode SE2 may be connected to the source region of the second active pattern ACT2 through a contact hole extending through the gate insulating layer GI and the interlayer insulating layer ILD. The third source electrode SE3 may be connected to the source region of the third active pattern ACT3 through a contact hole extending through the gate insulating layer GI and the interlayer insulating layer ILD.

The first, second, and third drain electrodes DE1, DE2, and DE3 may be disposed on the interlayer insulating layer ILD. The first drain electrode DE1 may be connected to the drain region of the first active pattern ACT1 through a contact hole extending through the gate insulating layer GI and the interlayer insulating layer ILD. The second drain electrode DE2 may be connected to the drain region of the second active pattern ACT2 through a contact hole extending through the gate insulating layer GI and the interlayer insulating layer ILD. The third drain electrode DE3 may be connected to the drain region of the third active pattern ACT3 through a contact hole extending through the gate insulating layer GI and the interlayer insulating layer ILD.

For example, each of the first, second, and third source electrodes SE1, SE2, and SE3 may include a metal, an alloy, a metal nitride, a conductive metal oxide, a transparent conductive material, and the like. These may be used alone or in combination with each other. The first, second, and third drain electrodes DE1, DE2, and DE3 may be formed through the same process as the first, second, and third source electrodes SE1, SE2, and SE3 and may include the same material.

Accordingly, the first transistor TR1 including the first active pattern ACT1, the first gate electrode GAT1, the first source electrode SE1, and the first drain electrode DE1 may be disposed on the first substrate SUB1; the second transistor TR2 including the second active pattern ACT2, the second gate electrode GAT2, the second source electrode SE2, and the second drain electrode DE2 may be disposed on the first substrate SUB1; and the third transistor TR3 including the third active pattern ACT3, the third gate electrode GAT3, the third source electrode SE3, and the third drain electrode DE3 may be disposed on the first substrate SUB1.

The via insulating layer VIA may be disposed on the interlayer insulation layer ILD. The via insulating layer VIA may sufficiently cover the first, second, and third source electrodes SE1, SE2, and SE3 and the first, second, and third drain electrodes DE1, DE2, and DE3. The via insulating layer VIA may include an organic material. For example, the via insulating layer VIA may include phenolic resin, polyacrylates resin, polyimides rein, polyamides resin, siloxane resin, epoxy resin, and the like. These may be used alone or in combination with each other.

A pixel electrode layer may be disposed on the via insulating layer VIA. The pixel electrode layer may include first, second, and third pixel electrodes PE1, PE2, and PE3. The first pixel electrode PE1 is in the first light emitting area EA1, the second pixel electrode PE2 is in the second light emitting area EA2, and the third pixel electrode PE3 is in the third light emitting area EA3. The first pixel electrode PE1 may be connected to the first drain electrode DE1 through a contact hole that extends through the via insulating layer VIA, the second pixel electrode PE2 may be connected to the second drain electrode DE2 through a contact hole that extends through the via insulating layer VIA, and the third pixel electrode PE3 may be connected to the third drain electrode DE3 through a contact hole that extends through the via insulating layer VIA.

For example, each of the first, second, and third pixel electrodes PE1, PE2, and PE3 may include a metal, an alloy, a metal nitride, a conductive metal oxide, a transparent conductive material, and the like. These may be used alone or in combination with each other. In an embodiment, each of the first, second, and third pixel electrodes PE1, PE2, and PE3 may have a stacked structure including ITO/Ag/ITO. The first, second, and third pixel electrodes PE1, PE2, and PE3 may be formed through the same process and include the same material. For example, each of the first, second, and third pixel electrodes PE1, PE2, and PE3 may operate as an anode.

The pixel defining layer PDL may be disposed on the via insulating layer VIA. The pixel defining layer PDL may overlap the light blocking area BA. The pixel defining layer PDL may cover edges of each of the first, second, and third pixel electrodes PE1, PE2, and PE3. In addition, a pixel opening exposing at least a part of the upper surface of each of the first, second, and third pixel electrodes PE1, PE2, and PE3 may be defined in the pixel defining layer PDL. For example, the pixel defining layer PDL may include an inorganic material and/or an organic material. In an embodiment, the pixel defining layer PDL may include an organic material such as an epoxy resin, a siloxane resin, and the like. These may be used alone or in combination with each other. In another embodiment, the pixel defining layer PDL may include an inorganic material and/or an organic material including a light blocking material having a black color.

The first light emitting layer EML1 may be disposed on the first pixel electrode PE1, the second light emitting layer EML2 may be disposed on the second pixel electrode PE2, and the third light emitting layer EML3 may be disposed on the third pixel electrode PE3. Each of the first, second, and third light emitting layers EML1, EML2, and EML3 may include an organic material that emits a first light L1 of a predetermined color. In an embodiment, the first light L1 may be blue light.

The first common electrode CE1 may be disposed on the first light emitting layer EML1 and the pixel defining layer PDL, the second common electrode CE2 may be disposed on the second light emitting layer EML2 and the pixel defining layer PDL, and the third common electrode CE3 may be disposed on the third light emitting layer EML3 and the pixel defining layer PDL. For example, the first, second, and third common electrodes CE1, CE2, and CE3 may be continuously formed so they are connected to one another. For example, each of the first, second, and third common electrodes CE1, CE2, and CE3 may include a metal, an alloy, a metal nitride, a conductive metal oxide, a transparent conductive material, and the like. These may be used alone or in combination with each other. The first, second, and third common electrodes CE1, CE2, and CE3 may operate as cathode.

Accordingly, the first light emitting element LED1 including the first pixel electrode PE1, the first light emitting layer EML1, and the first common electrode CE1 may be disposed in the first light emitting area EA1 on the first substrate SUB1. The second light emitting element LED2 including the second pixel electrode PE2, the second light emitting layer EML2, and the second common electrode CE2 may be disposed in the second light emitting area EA2 on the first substrate SUB1. The third light emitting element LED3 including the third pixel electrode PE3, the third light emitting layer EML3, and the third common electrode CE3 may be disposed in the third light emitting area EA3 on the first substrate SUB1. Each of the first, second, and third light emitting elements LED1, LED2, and LED3 may emit blue light.

The first light emitting element LED1 may be electrically connected to the first transistor TR1, the second light emitting element LED2 may be electrically connected to the second transistor TR2, and the third light emitting element LED3 may be electrically connected to the third transistor TR3.

The encapsulation layer ENC may be disposed on the first, second, and third common electrodes CE1, CE2, and CE3. The encapsulation layer ENC may prevent impurities, moisture, air, and the like from permeating the first, second, and third light emitting elements LED1, LED2, and LED3 from the outside. The encapsulation layer ENC may include at least one inorganic layer and at least one organic layer. For example, the inorganic layer may include silicon oxide, silicon nitride, silicon oxynitride, and the like. These may be used alone or in combination with each other. The organic layer may include a polymer cured material such as polyacrylate and the like.

Referring further to FIG. 5, in an embodiment, the scattering layer SL including a base resin BS and a plurality of scattering particles SP dispersed in the base resin BS may be disposed on the encapsulation layer ENC. The scattering layer SL may scatter the first light L1 emitted from the first, second, and third light emitting elements LED1, LED2, and LED3. Accordingly, a wide viewing angle of the display device DD can be secured.

In an embodiment, the scattering layer SL may be disposed in the third light emitting area EA3 and light blocking area BA but not in the first and second light emitting areas EA1 and EA2. and the scattering layer SL may extend into at least a part of the light blocking area BA so as to overlap the bank layer BL. In this case, the scattering layer SL may serve as a column spacer (e.g., the column spacer CS of FIG. 3) for maintaining a constant gap between the lower structure 100 and the upper structure 200. In this case, the column spacer CS of FIG. 3 may be omitted. In addition, as the scattering layer SL is disposed to overlap the bank layer BL, color mixing between the first, second, and third light emitting areas EA1, EA2, and EA3 can be prevented.

A thickness TK of the scattering layer SL may be about 10 nm to about 10000 nm. When the thickness TK of the scattering layer SL is less than 10 nm, a wide viewing angle may not be secured. When the thickness TK of the scattering layer SL is greater than 10000 nm, light efficiency of the display device DD may decrease.

The base resin BS may include a resin having high light transmittance such as photoresist, silicone resin, epoxy resin, and the like. These may be used alone or in combination with each other.

Each of the scattering particles SP may include an inorganic material. For example, each of the scattering particles SP may include TiO2, Sb2O3, CaO, In2O3, and the like. These may be used alone or in combination with each other. However, embodiments of the present disclosure are not limited thereto.

Next, the upper structure 200 will be described.

Referring back to FIG. 4, the second substrate SUB2 may be formed of a transparent resin substrate. The second substrate SUB2 may transmit the first light L1 emitted from the first, second, and third light emitting elements LED1, LED2, and LED3. For example, the second substrate SUB2 may include an insulating material such as glass or plastic. Alternatively, the second substrate SUB2 may include an organic polymer material such as polycarbonate (PC), polyethylene (PE), polypropylene (PP), and the like. These may be used alone or in combination with each other.

A color filter layer may be disposed under the second substrate SUB2. The color filter layer may selectively transmit light having a specific wavelength. The color filter layer may include the first color filter CF1, the second color filter CF2, and the third color filter CF3.

The first color filter CF1 may selectively transmit light of a first color (e.g., red light Lr). The first color filter CF1 may be positioned in the first light emitting area EA1 and the light blocking area BA. In this case, the first color filter CF1 may not be present in the second and third light emitting areas EA2 and EA3.

The second color filter CF2 may selectively transmit light of a second color (e.g., green light Lg). The second color filter CF2 may be positioned in the second light emitting area EA2 and the light blocking area BA. In this case, the second color filter CF2 may not be present in the first and third light emitting areas EA1 and EA3.

The third color filter CF3 may selectively transmit light of a third color (e.g., blue light Lb). The third color filter CF3 may be positioned in the third light emitting area EA3 and the light blocking area BA. In this case, the third color filter CF3 may not be present in the first and second light emitting areas EA1 and EA2.

The first capping layer CL1 may be disposed under the color filter layer. The first capping layer CL1 may block external impurities to prevent contamination of the color filter layer. For example, the first capping layer CL1 may include an inorganic material such as silicon oxide, silicon nitride, silicon oxynitride, and the like. These may be used alone or in combination with each other.

The bank layer BL may be disposed under the first capping layer CL1. The bank layer BL may be positioned in the light blocking area BA. Depending on the embodiment, the bank layer BL may be formed in less than all of the light blocking area BA. A space capable of accommodating a material forming a color conversion layer may be formed in the bank layer BL. For example, the bank layer BL may have a lattice shape in plan view. In an embodiment, the bank layer BL may define a first opening OP1 in the first light emitting area EA1, a second opening OP2 in the second light emitting area EA2, and a third opening OP3 in the third light emitting area EA3. As shown in FIG. 4, there is no bank layer BL material in these openings OP1, OP2, OP3.

The bank layer BL may include an inorganic material and/or an organic material. For example, the bank layer BL may include an organic material such as polyimide. Alternatively, the bank layer BL may include an inorganic material and/or an organic material including a blocking material having a black color.

The first color conversion layer CCL1 and the second color conversion layer CCL2 may be disposed under the first capping layer CL1. The first color conversion layer CCL1 may be in the first light emitting area EA1, and the second color conversion layer CCL2 may be in the second light emitting area EA2. Specifically, the first color conversion layer CCL1 may be disposed in the first opening OP1 of the bank layer BL, and the second color conversion layer CCL2 may be disposed in the second opening OP2 of the bank layer BL. Accordingly, the first color conversion layer CCL1 may have the same planar shape as the first opening OP1, and the second color conversion layer CCL2 may have the same planar shape as the second opening OP2.

In an embodiment, the scattering layer SL may not overlap the first and second color conversion layers CCL1 and CCL2 and overlap the third opening OP3 of the bank layer BL in plan view. In some cases, the scattering layer SL may not overlap the first and second color conversion layers CCL1 and CCL2 and completely overlap the third opening OP3 of the bank layer BL in plan view.

FIG. 6 is a cross-sectional view for explaining a first color conversion layer and a second color conversion layer of FIG. 4.

Further referring to FIG. 6, the first color conversion layer CCL1 may include first quantum dots 11c excited by the first light L1 emitted from the first light emitting element LED1 to emit light of a first color (e.g., the red light Lr). In addition, the first color conversion layer CCL1 may further include a first base resin 11b in which the first scattering particles 11a are dispersed.

The second color conversion layer CCL2 may include second quantum dots 12c excited by the first light L1 emitted from the second light emitting element LED2 to emit light of a second color (e.g., the green light Lg). In addition, the second color conversion layer CCL2 may further include a second base resin 12b in which the second scattering particles 12a are dispersed.

Each of the first and second base resins 11b and 12b may include a resin having high light transmittance such as photoresist, silicone resin, epoxy resin, and the like. These may be used alone or in combination with each other.

For example, the first and second scattering particles 11a and 12a may scatter and emit light emitted from the first and second light emitting elements LED1 and LED2. In addition, the first and second scattering particles 11a and 12a may include the same material as each other.

Accordingly, the first light emitting area EA1 may emit red light Lr, and the second light emitting area EA2 may emit green light Lg.

Referring back to FIG. 4, the second capping layer CL2 may be disposed under the first color conversion layer CCL1, the second color conversion layer CCL2, the bank layer BL, and the first capping layer CL1. The second capping layer CL2 may be disposed on the surface of each of the first color conversion layer CCL1, the second color conversion layer CCL2, the bank layer BL, and the first capping layer CL1. The second capping layer CL2 may prevent moisture permeation to prevent deterioration of the first color conversion layer CCL1 and the second color conversion layer CCL2. For example, the second capping layer CL2 may include an inorganic material such as silicon oxide, silicon nitride, silicon oxynitride, and the like. These may be used alone or in combination with each other.

The filling layer 300 may be disposed between the lower structure 100 and the upper structure 200. That is, the filling layer 300 may occupy a space between the lower structure 100 and the upper structure 200.

In an embodiment, a homogeneous resin (i.e., resin without scattering particles 11a/12a) having high light transmittance may be placed in the third opening OP3 of the bank layer BL. Accordingly, light efficiency of the display device DD can be improved, and a high-resolution display device DD can be implemented. Here, the resin filled in the third opening OP3 of the bank layer BL may be defined as “a light transmission layer.” The light transmission layer may transmit the first light L1 emitted from the third light emitting element LED3. Accordingly, the third light emitting area EA3 may emit blue light Lb.

For example, a part of the filling layer 300 may be placed in the third opening OP3 of the bank layer BL. Alternatively, a resin having high light transmittance without scattering particles may be filled in the third opening OP3 of the bank layer BL through a separate process.

However, although the display device DD is described as including two substrates in FIG. 4, embodiments of the present disclosure are not limited thereto. For example, the display device DD may have a single substrate structure. In this case, the bank layer BL, the first and second color conversion layers CCL1 and CCL2, and the first, second, and third color filters CF1, CF2 and CF3 may be disposed on the encapsulation layer ENC.

In addition, although it has been described in FIG. 4 that the first and second color conversion layers CCL1 and CCL2 and the bank layer BL are included in the upper structure 200, embodiments of the present disclosure are not limited thereto. For example, the first and second color conversion layers CCL1 and CCL2 and the bank layer BL may be included in the lower structure 100.

The display device DD according to an embodiment of the present disclosure may include the scattering layer SL disposed on the pixel electrode layer, the bank layer BL disposed on the scattering layer SL and defining first, second, and third openings OP1, OP2, and OP3, the first color conversion layer CCL1 disposed in the first opening OP1 and including first quantum dots, and the second color conversion layer CCL2 disposed in the second opening OP2 and including second quantum dots. The scattering layer SL includes the base resin BS and the plurality of scattering particles SP dispersed in the base resin BS. The scattering layer SL may overlap the third opening OP3 and not completely overlap the first and second color conversion layers CCL1 and CCL2 in plan view. Accordingly, viewing angle characteristic of the display device DD can be improved.

In addition, in the display device DD according to an embodiment of the present disclosure, a homogeneous resin, which is resin having high light transmittance without scattering particles 11a/12a, may be placed in the third opening OP3. Accordingly, light efficiency of the display device DD can be improved, and a high-resolution display device DD can be implemented.

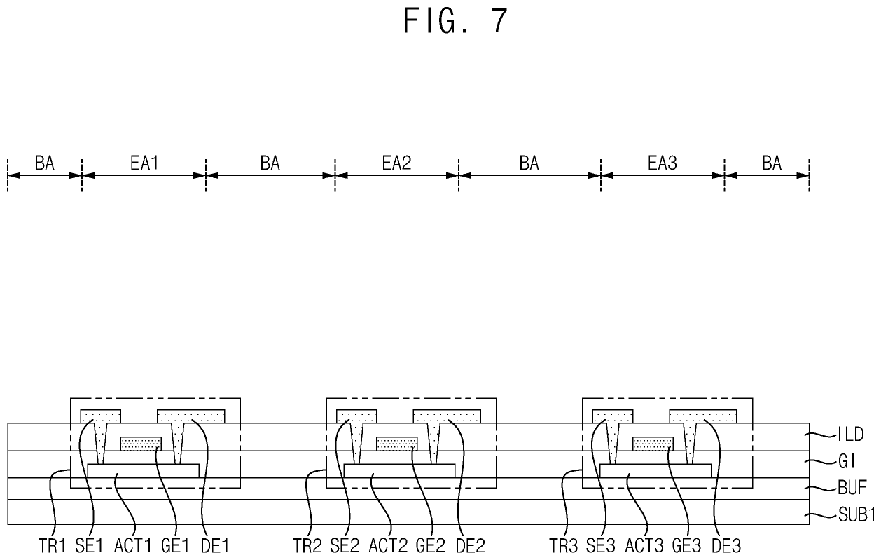

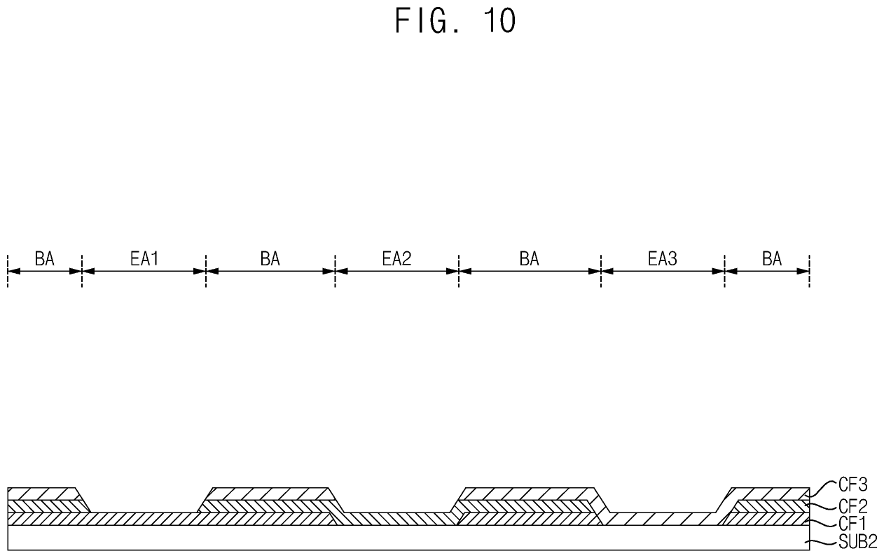

FIGS. 7, 8, 9, 10, 11, 12, 13, and 14 are cross-sectional views illustrating a method of manufacturing the display device of FIG. 4. For example, FIGS. 7, 8, and 9 are cross-sectional views for explaining a method of manufacturing the lower structure 100 of FIG. 4, and FIGS. 10, 11, 12, 13, and 14 are cross-sectional views for explaining a method of manufacturing the upper structure 200 of FIG. 4.

Referring to FIG. 7, the buffer layer BUF1, the first, second, and third transistors TR1, TR2, and TR3, the gate insulating layer GI, and the interlayer insulating layer ILD may be sequentially formed on the first substrate SUB1.

The first transistor TR1 may include the first active pattern ACT1 formed on the buffer layer BUF, the first gate electrode GE1 formed on the gate insulating layer GI, and the first source electrode SE1 and the first drain electrode DE1 formed on the interlayer insulating layer ILD.

The second transistor TR2 may include the second active pattern ACT2 formed on the buffer layer BUF, the second gate electrode GE2 formed on the gate insulating layer GI, and the second source electrode SE2 and the second drain electrode DE2 formed on the interlayer insulating layer ILD.

The third transistor TR3 may include the third active pattern ACT3 formed on the buffer layer BUF, the third gate electrode GE3 formed on the gate insulating layer GI, and the third source electrode SE3 and the third drain electrode DE3 formed on the interlayer insulating layer ILD.

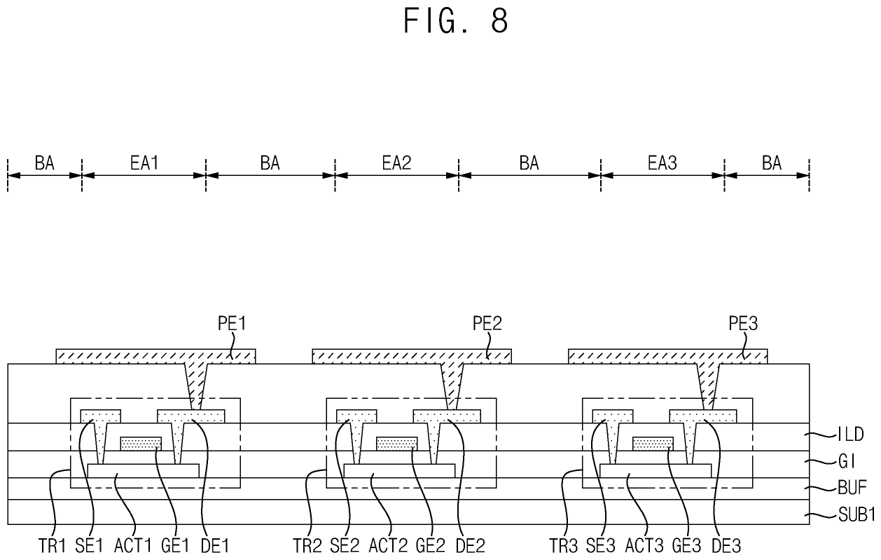

Referring to FIG. 8, the via insulating layer VIA may be formed on the interlayer insulation layer ILD. The via insulating layer VIA may sufficiently cover the first, second, and third source electrodes SE1, SE2, and SE3 and the first, second, and third drain electrodes DE1, DE2, and DE3. For example, the via insulating layer VIA may be formed using an organic material.

The first, second, and third pixel electrodes PE1, PE2, and PE3 may be formed on the via insulating layer VIA. The first pixel electrode PE1 may be connected to the first drain electrode DE1 through a first contact hole formed by removing a part of the via insulating layer VIA, the second pixel electrode PE2 may be connected to the second drain electrode DE2 through a second contact hole formed by removing a part of the via insulating layer VIA, and the third pixel electrode PE3 may be connected to the third drain electrode DE3 through a third contact hole formed by removing a part of the via insulating layer VIA.

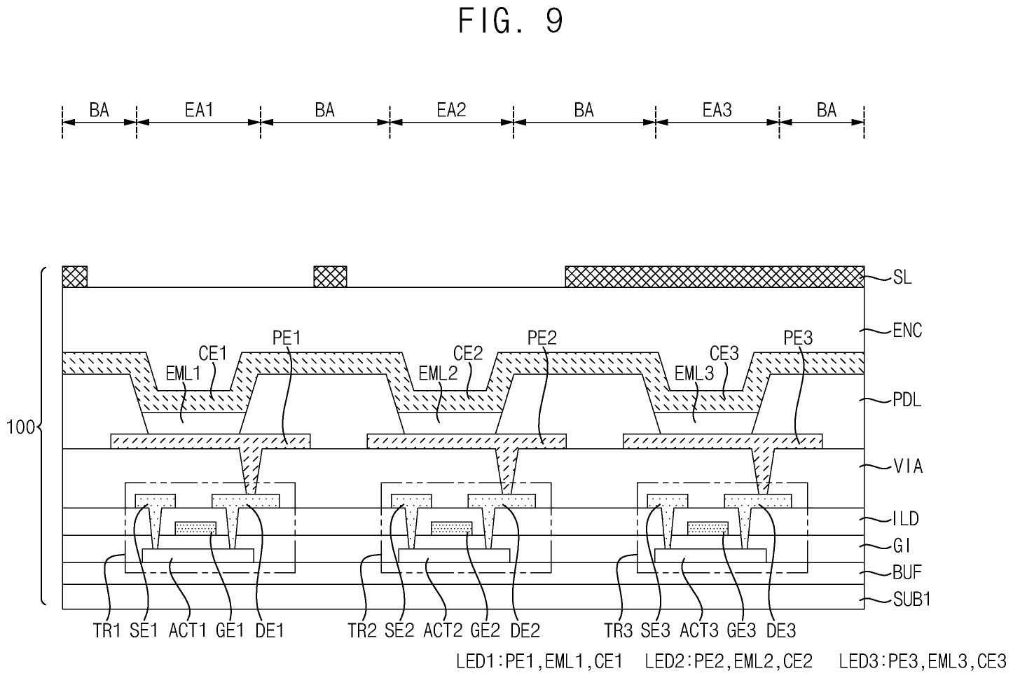

Referring to FIG. 9, the pixel defining layer PDL may be formed on the via insulating layer VIA and the first, second, and third pixel electrodes PE1, PE2, and PE3. A pixel opening exposing at least a part of the upper surface of each of the first, second, and third pixel electrodes PE1, PE2, and PE3 may be formed in the pixel defining layer PDL. For example, the pixel defining layer PDL may be formed using an inorganic material and/or an organic material.

The first light emitting layer EML1 may be formed on the first pixel electrode PE1, the second light emitting layer EML2 may be formed on the second pixel electrode PE2, and the third light emitting layer EML3 may be formed on the third pixel electrode PE3. For example, each of the first, second and third light emitting layers EML1, EML2, and EML3 may be formed using an organic material that emits predetermined light.

The first, second, and third common electrodes CE1, CE2, and CE3 may be formed on the pixel defining layer PDL and the first, second, and third light emitting layers EML1, EML2, and EML3. The first, second, and third common electrodes CE1, CE2, and CE3 may be formed as a single continuous layer. That is, the first, second, and third common electrodes CE1, CE2, and CE3 may be entirely formed in the first light emitting area EA1, the second light emitting area EA2, the third light emitting area EA3, and the light blocking area BA.

The encapsulation layer ENC may be formed on the first, second, and third common electrodes CE1, CE2, and CE3. The encapsulation layer ENC may include at least one inorganic encapsulation layer and at least one organic encapsulation layer, and have a planarizing effect by providing a flat and even surface.

The scattering layer SL may be formed on the encapsulation layer ENC. The scattering layer SL may not be formed in the first and second light emitting areas EA1 and EA2 but may be formed in an entirety of the third light emitting area EA3 and a part of the light blocking area BA. The scattering layer SL may include a base resin and a plurality of scattering particles dispersed in the base resin.

Accordingly, the lower structure 100 illustrated in FIG. 4 may be formed.

Referring to FIG. 10, the first color filter CF1 may be formed on the second substrate SUB2. The first color filter CF1 may be formed in the first light emitting area EA1 and the light blocking area BA. The first color filter CF1 may be a red color filter that transmits red light. For example, the first color filter CF1 may be formed from a color filter composition including a red pigment and/or a red pigment.

The second color filter CF2 may be formed on the second substrate SUB2 and the first color filter CF1. The second color filter CF2 may be formed in the second light emitting area EA2 and the light blocking area BA. The second color filter CF2 may be a green color filter that transmits green light. For example, the second color filter CF2 may be formed from a color filter composition including a green pigment and/or a green pigment. In the light blocking area BA where the first color filter CF1 is already formed, the second color filter CF2 may be formed on the first color filter CF1.

The third color filter CF3 may be formed on the second color filter CF2 and the second substrate SUB2. The third color filter CR3 may be a blue color filter that transmits blue light. The third color filter CF3 may be formed from a color filter composition including a blue pigment and/or a blue pigment. In the light blocking area where the first and second color filters CF1, CF2 are already formed, the third color filter CF3 may be formed on top of the second color filter CF2.

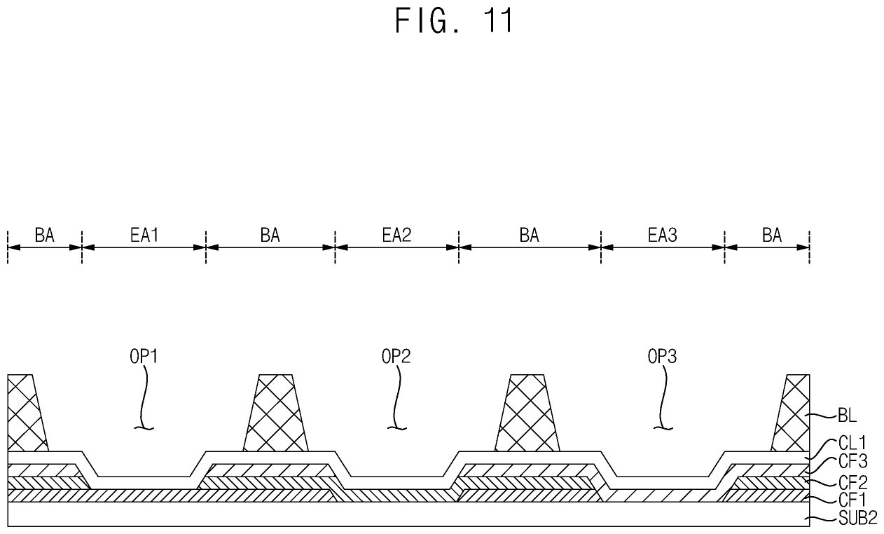

Referring to FIG. 11, the first capping layer CL1 may be formed on the first, second, and third color filters CF1, CF2, and CF3. For example, the first capping layer CL1 may be formed using an inorganic material.

The bank layer BL may be formed on the first capping layer CL1. The first opening OP1 overlapping the first light emitting area EA1, the second opening OP2 overlapping the second light emitting area EA2, and the third opening OP3 overlapping the third light emitting area EA3 may be formed in the bank layer BL. Each of the first, second, and third openings OP1, OP2, and OP3 may expose at least a part of the upper surface of the first capping layer CL1. For example, the bank layer BL may be formed using an organic material.

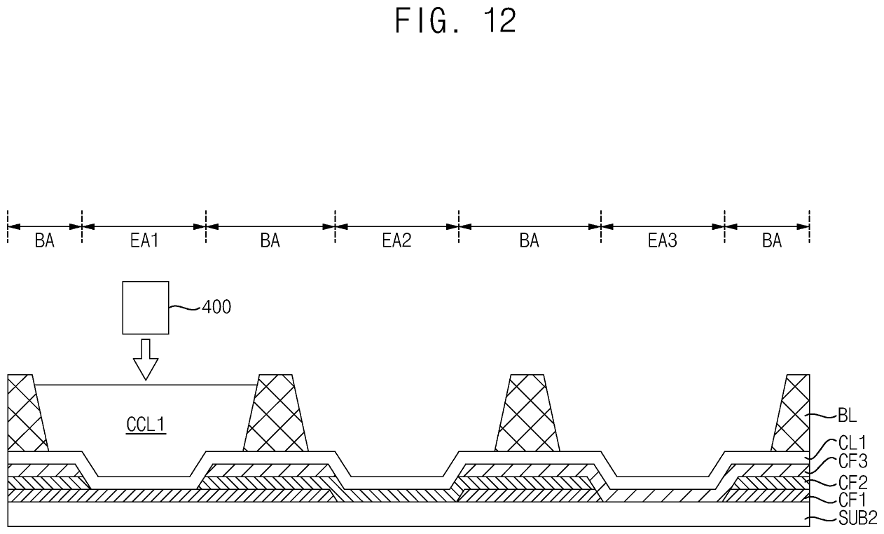

Referring to FIG. 12, an inkjet device 400 may drip a first ink composition into the first opening OP1. Here, the first ink composition may be a material forming the first color conversion layer CCL1. The first color conversion layer CCL1 may be formed by repeatedly dropping the first ink composition into the first opening OP1 from the inkjet device 400.

Then, after the inkjet device 400 moves onto the second opening OP2, the second color conversion layer CCL2 may be formed by repeatedly dropping a second ink composition onto the second opening OP2. Here, the second ink composition may be a material forming the second color conversion layer CCL2.

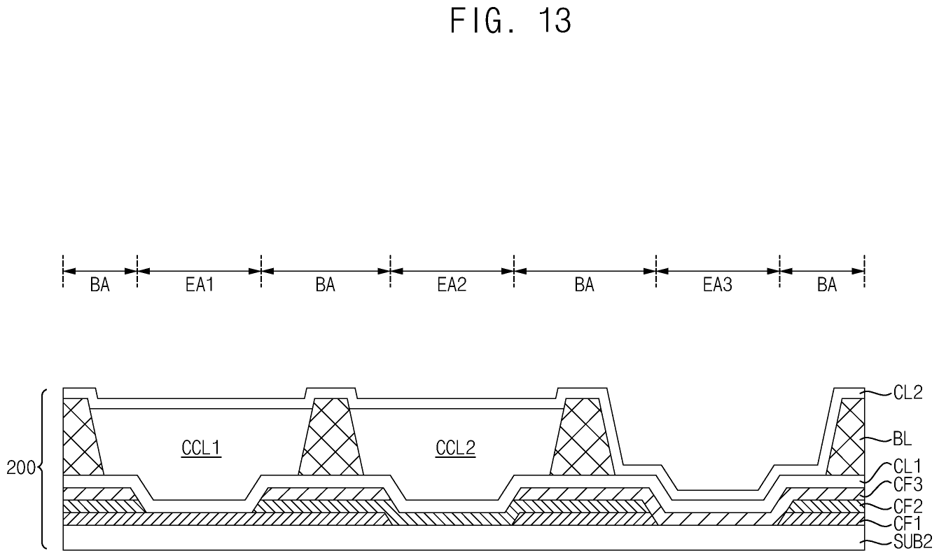

Referring to FIG. 13, the second capping layer CL2 may be formed on the bank layer BL, the first color conversion layer CCL1, the second color conversion layer CCL2, and the first capping layer CL1. For example, the second capping layer CL2 may be formed using an inorganic material.

Accordingly, the upper structure 200 illustrated in FIG. 4 may be formed.

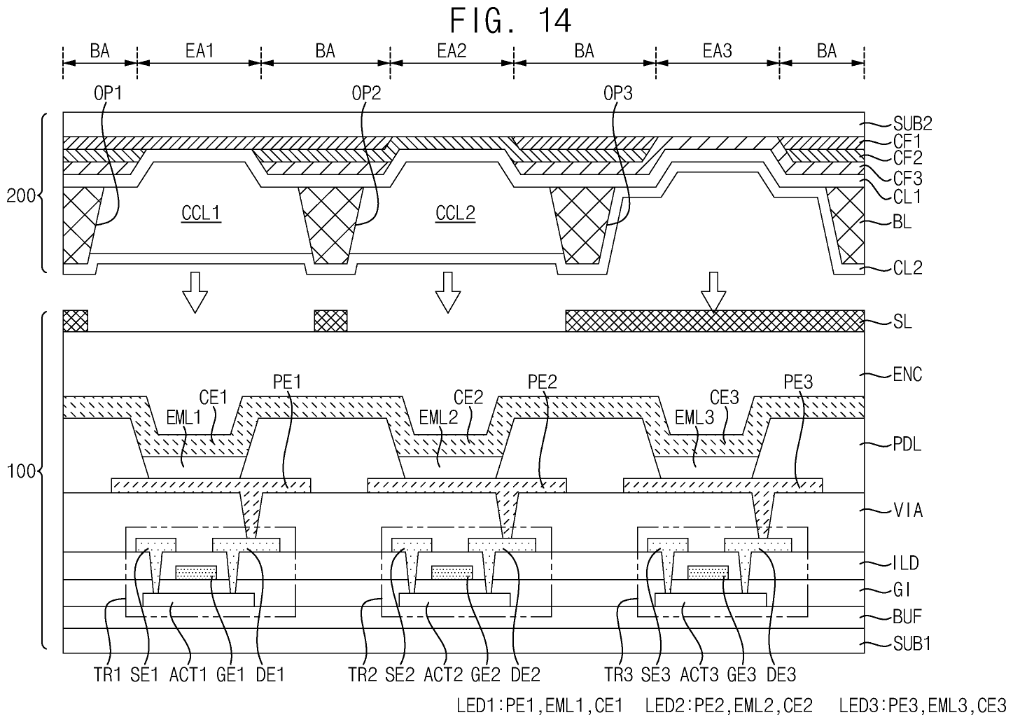

Referring to FIGS. 4 and 14, the lower structure 100 and the upper structure 200 may be coupled. Specifically, the lower structure 100 and the upper structure 200 may be coupled through a sealing portion (e.g., the sealing portion 350 of FIG. 2). In this case, the empty space between the lower structure 100 and the upper structure 200 may be filled with the filling layer 300. When the empty space is filled with the filling layer 300, a part of the filling layer 300 may also be filled in the third opening OP3 of the bank layer BL. Accordingly, a light transmission layer may be formed in the third opening OP3. As the lower structure 100 and the upper structure 200 are coupled, the display device DD illustrated in FIG. 4 may be manufactured.

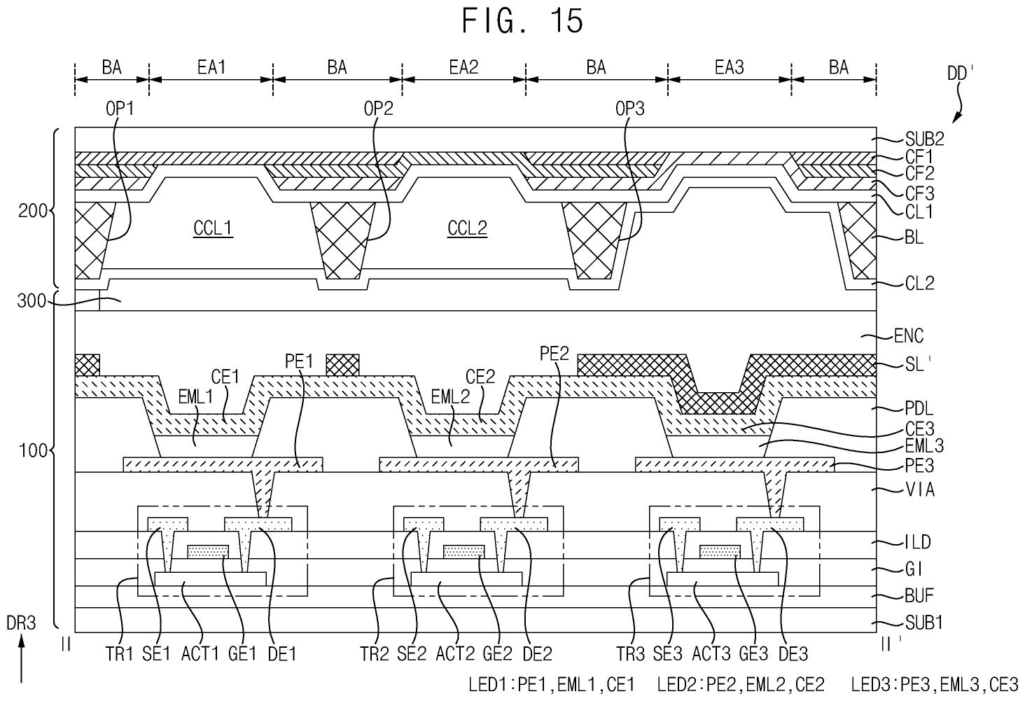

FIG. 15 is a cross-sectional view illustrating a display device according to another embodiment of the present disclosure.

Referring to FIG. 15, the display device DD′ according to an embodiment may include the lower structure 100, the filling layer 300, and the upper structure 200. Here, the lower structure 100 may include a first substrate SUB1, a buffer layer BUF, first, second, and third transistors TR1, TR2, and TR3, a gate insulating layer GI, an interlayer insulating layer ILD, an via insulating layer VIA, a pixel defining layer PDL, first, second, and third light emitting elements LED1, LED2, and LED3, an encapsulation layer ENC, and a scattering layer SL′. The upper structure 200 may include a second substrate SUB2, first, second, and third color filters CF1, CF2, and CF3, a first capping layer CL1, a bank layer BL, first and second color conversion layers CCL1 and CCL2, and a second capping layer CL2. However, the display device DD′ described with reference to FIG. 15 may be substantially the same as or similar to the display device DD described with reference to FIG. 4 except for the location of the scattering layer and the SL′. In the following description of FIG. 15, redundant descriptions are omitted or simplified.

In an embodiment, the scattering layer SL′ may be disposed between the first, second, and third light emitting layers EML1, EML2, and EML3 and the encapsulation layer ENC. Specifically, the scattering layer SL′ may be disposed between the first, second, and third common electrodes CE1, CE2, and CE3 and the encapsulation layer ENC. In this case, the scattering layer SL′ may directly contact the encapsulation layer ENC.

The scattering layer SL′ may include a base resin including a resin having high light transmittance and a plurality of scattering particles dispersed in the base resin. For example, each of the scattering particles may include an inorganic material.

In an embodiment, the scattering layer SL′ may not overlap the first and second light emitting areas EA1 and EA2 and overlap the third light emitting area EA3. In addition, the scattering layer SL′ may extend to at least a part of the light-blocking area BA so as to overlap the bank layer BL.

In an embodiment, the scattering layer SL′ may not overlap the first and second color conversion layers CCL1 and CCL2 but overlap the third opening OP3 of the bank layer BL. Specifically, the scattering layer SL′ may not overlap the first and second color conversion layers CCL1 and CCL2 but overlap the entire third opening OP3 of the bank layer BL.

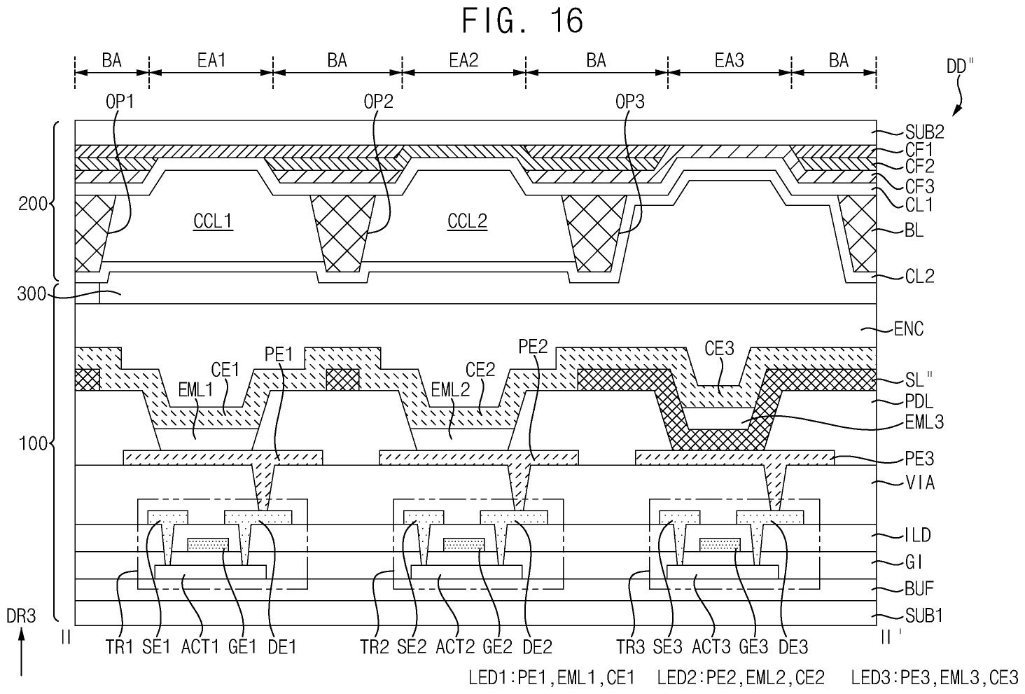

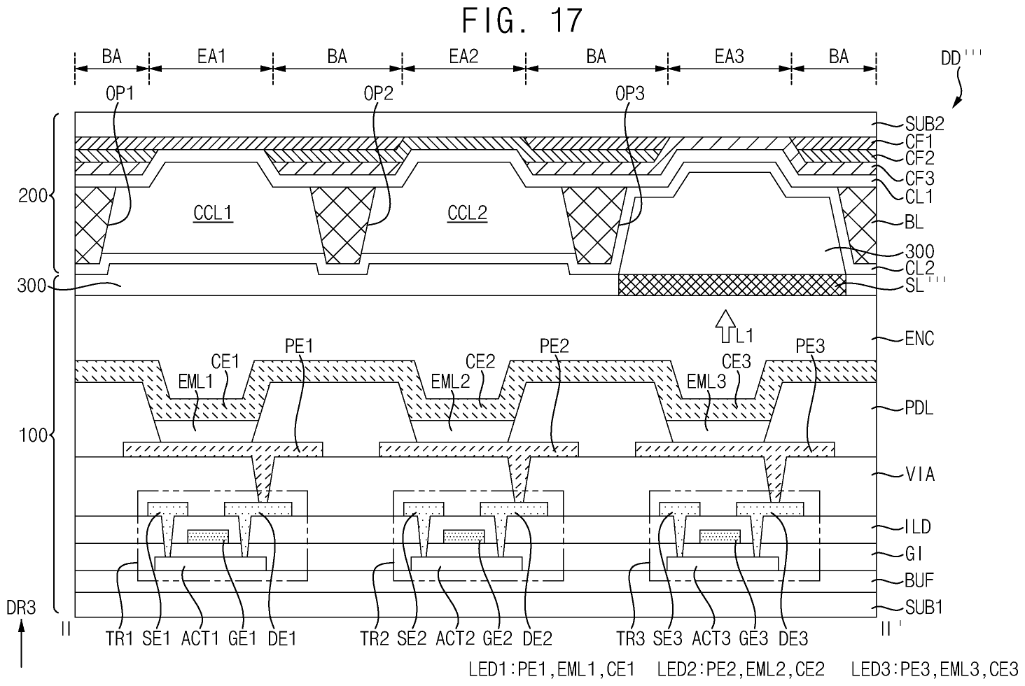

FIG. 16 is a cross-sectional view illustrating a display device according to yet another embodiment of the present disclosure.

Referring to FIG. 16, the display device DD″ according to an embodiment may include the lower structure 100, the filling layer 300, and the upper structure 200. Here, the lower structure 100 may include a first substrate SUB1, a buffer layer BUF, first, second, and third transistors TR1, TR2, and TR3, a gate insulating layer GI, an interlayer insulating layer ILD, an via insulating layer VIA, a pixel defining layer PDL, first, second, and third light emitting elements LED1, LED2, and LED3, an encapsulation layer ENC, and a scattering layer SL″. The upper structure 200 may include a second substrate SUB2, first, second, and third color filters CF1, CF2, and CF3, a first capping layer CL1, a bank layer BL, first and second color conversion layers CCL1 and CCL2, and a second capping layer CL2. However, the display device DD″ described with reference to FIG. 16 may be substantially the same as or similar to the display device DD described with reference to FIG. 4 except for the location of the scattering layer SL″. In the following description of FIG. 16, redundant descriptions are omitted or simplified.

In an embodiment, a part of the scattering layer SL″ may be disposed between the pixel defining layer PDL and the encapsulation layer ENC, and another part of the scattering layer SL″ may be disposed between the third pixel electrode PE3 and the third light emitting layer EML3. That is, the scattering layer SL″ may be disposed after the first, second, and third pixel electrodes PE1, PE2, and PE3 and the pixel defining layer PDL are disposed.

The scattering layer SL″ may include a base resin including a resin having a high light transmittance and a plurality of scattering particles dispersed in the base resin. For example, each of the scattering particles may include an inorganic material.

In an embodiment, the scattering layer SL″ may not be disposed in the first and second light emitting areas EA1 and EA2 but be disposed in the third light emitting area EA3. In addition, the scattering layer SL″ may extend into at least a part of the light-blocking area BA so as to overlap the bank layer BL.

In an embodiment, the scattering layer SL″ may not overlap the first and second color conversion layers CCL1 and CCL2 but overlap the third opening OP3 of the bank layer BL. In some embodiments, the scattering layer SL″ may not overlap the first and second color conversion layers CCL1 and CCL2 but overlap the entirety of the third opening OP3 of the bank layer BL.

FIG. 17 is a cross-sectional view illustrating a display device according to yet another embodiment of the present disclosure.

Referring to FIG. 17, the display device DD′″ according to an embodiment may include the lower structure 100, the filling layer 300, and the upper structure 200. Here, the lower structure 100 may include a first substrate SUB1, a buffer layer BUF, first, second, and third transistors TR1, TR2, and TR3, a gate insulating layer GI, an interlayer insulating layer ILD, an via insulating layer VIA, a pixel defining layer PDL, first, second, and third light emitting elements LED1, LED2, and LED3, an encapsulation layer ENC, and a scattering layer SL′″. The upper structure 200 may include a second substrate SUB2, first, second, and third color filters CF1, CF2, and CF3, a first capping layer CL1, a bank layer BL, first and second color conversion layers CCL1 and CCL2, and a second capping layer CL2. However, the display device DD′″ described with reference to FIG. 17 may be substantially the same as or similar to the display device DD described with reference to FIG. 4 except for the location of the scattering layer SL′″. In the following description of FIG. 17, redundant descriptions are omitted or simplified.

In an embodiment, the scattering layer SL′″ may be disposed on the encapsulation layer ENC. However, unlike shown in FIG. 17, embodiments of the present disclosure are not limited thereto. In another embodiment, the scattering layer SL′″ may be disposed between at least one of the first, second, and third common electrodes CE1, CE2, and CE3 and the encapsulation layer ENC. In another embodiment, the scattering layer SL′″ may be disposed between the third pixel electrode PE3 and the third light emitting layer EML3.

The scattering layer SL′″ may include a base resin including a resin having high light transmittance and a plurality of scattering particles dispersed in the base resin. For example, each of the scattering particles may include an inorganic material.

In an embodiment, the scattering layer SL′″ may not be disposed in the first and second light emitting areas EA1 and EA2 but be present in the third light emitting area EA3. In other words, the scattering layer SL′″ may not overlap the first and second color conversion layers CCL1 and CCL2 but overlap the third opening OP3 of the bank layer BL. In addition, the scattering layer SL′″ does not overlap the bank layer BL.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a pixel electrode layer disposed on a substrate;
a light emitting layer disposed on the pixel electrode layer;
a bank layer disposed on the light emitting layer and defining first, second, and third openings;
a first color conversion layer disposed in the first opening and including first quantum dots; and
a scattering layer disposed in a layer between the pixel electrode layer and the bank layer such that the scattering layer and at least a part of the first color conversion layer cover mutually exclusive parts of the substrate, the scattering layer including a base resin and a plurality of scattering particles dispersed in the base resin.

2. The display device of claim 1, wherein the scattering layer forms a base of the third opening.

3. The display device of claim 2, further comprising:
a second color conversion layer disposed in the second opening and including quantum dots,
wherein the scattering layer and at least a part of the second color conversion layer cover mutually exclusive parts of the substrate.

4. The display device of claim 2, wherein the scattering layer further overlaps the bank layer.

5. The display device of claim 1, wherein the scattering layer overlaps less than all of the bank layer.

6. The display device of claim 1, further comprising:
an encapsulation layer disposed on the light emitting layer,
wherein the scattering layer is disposed in a layer between the encapsulation layer and the bank layer.

7. The display device of claim 1, further comprising:
an encapsulation layer disposed on the light emitting layer,
wherein the scattering layer is disposed between the light emitting layer and the encapsulation layer.

8. The display device of claim 1, further comprising:
a pixel defining layer defining a pixel opening extending to at least a part of the pixel electrode layer; and
an encapsulation layer disposed on the light emitting layer and the pixel defining layer,
wherein a part of the scattering layer is disposed between the pixel defining layer and the encapsulation layer and another part of the scattering layer is disposed between the pixel electrode layer and the light emitting layer.

9. The display device of claim 1, further comprising a resin in the third opening, the resin being homogeneous and having high light transmittance.

10. The display device of claim 1, wherein the scattering layer has a thickness of about 10 nm to about 10000 nm.

11. The display device of claim 1, wherein each of the scattering particles includes at least one of TiO₂, Sb₂O₃, Cao, and In₂O₃.

12. A display device comprising:
a substrate including first, second, and third emitting areas that emit light of different colors and a light blocking area between the first, second, and third emitting areas;
a pixel electrode layer disposed on the substrate;
first, second, and third light emitting layers disposed on the pixel electrode layer in the first, second, and third emitting areas, respectively;
a bank layer disposed on the first, second, and third light emitting layers and defining first, second, and third openings above the first, second, and third emitting areas, respectively;
a first color conversion layer disposed in the first opening and including first quantum dots; and
a scattering layer disposed in a layer between the pixel electrode layer and the bank layer such that the scattering layer and at least a part of the first color conversion layer cover mutually exclusive parts of the substrate, and the scattering layer including a base resin and a plurality of scattering particles dispersed in the base resin.

13. The display device of claim 12, wherein the scattering layer overlaps the third light emitting area.

14. The display device of claim 12, further comprising:
a second color conversion layer disposed in the second opening and including quantum dots.

15. The display device of claim 12, wherein the scattering layer overlaps the bank layer.

16. The display device of claim 12, wherein the scattering layer partially overlaps the bank layer.

17. The display device of claim 12, further comprising:
an encapsulation layer disposed on the light emitting layer,
wherein the scattering layer is disposed in a layer between the encapsulation layer and the bank layer.

18. The display device of claim 12, further comprising:
an encapsulation layer disposed on the light emitting layer,
wherein the scattering layer is disposed between the light emitting layer and the encapsulation layer.

19. The display device of claim 12, further comprising a resin in the third opening, the resin being homogeneous and having high light transmittance.

20. The display device of claim 12, wherein the first light emitting area emits red light, the second light emitting area emits green light, and the third light emitting area emits blue light.
